(19) United States
(12) Patent Application Publication
(10) Pub. No.: US 2014/0149815 A1
(43) Pub. Date: May 29, 2014

(54) SYSTEM AND METHOD FOR PROGRAMMING CHIPS ON CIRCUIT BOARD THROUGH BOUNDARY SCAN TECHNOLOGY

(71) Applicants: INVENTEC (PUDONG) TECHNOLOGY CORPORATION, Shanghai (CN); INVENTEC CORPORATION, Taipei (TW)

(72) Inventor: Meng SUN, Shanghai (CN)

(73) Assignees: INVENTEC CORPORATION, Taipei (TW); INVENTEC (PUDONG) TECHNOLOGY CORPORATION, Shanghai (CN)

(21) Appl. No.: 13/795,184

(22) Filed: Mar. 12, 2013

(30) Foreign Application Priority Data
Nov. 27, 2012 (CN) 201210492692.7

(51) Int. Cl. G01R 31/3177

(52) U.S. Cl. CPC G01R 31/3177
USPC 714/727

(57) ABSTRACT

A system and a method for programming chips on circuit board through boundary scan technology are provided. Each chip and a Joint Test Action Group (JTAG) interface on a target circuit board are connected in series according to a boundary scan technology to form a boundary scan chain. A read and write device selects a corresponding chip according to programming data, pushes the programming data to the selected chip through the JTAG interface by using the boundary scan technology to perform programming, thereby achieving the technical effects of simplifying the programming of different chips on circuit board and enhancing the efficiency of programming chips.

### BACKGROUND OF THE INVENTION

1. Field of Invention

The present invention relates to a system and a method for programming chips, and more particularly to a system and a method for programming chips on circuit board through boundary scan technology.

2. Related Art

Generally speaking, a circuit board has a plurality of chips, each having a separate function or several being combined to implement a complex function. Some chips on the circuit board are used for data storage, such as an electrically-erasable programmable read-only memory (EEPROM) chip, a non-volatile random access memory chip, or a flash memory chip.

The above chips are generally used for storing important hardware related information, such as firmware versions of important components such as a network controller, a storage controller, and a motherboard controller, a media access control (MAC) address, a WWN (World Wide Name), and data. If such information is missing or an error occurs to the information, the entire circuit board might encounter the severe problem of failing to provide functions, or even fail to work normally.

Of course, the important information hardly changes after production; however, when a problem occurs, the important information needs to be programmed onto the chip again. Chip manufacturers adopt different technical means for the update and programming of chips. For example, special software and hardware tools are required to program chips, dedicated equipment or special methods are required to program chips, or even, chips needs to be desoldered from a circuit board, dedicated equipment is used to program chips, and the chip is finally soldered back to the circuit board, which makes the work of programming chips more complex, the efficiency low, and the cost high.

In conclusion, it can be known that at present the problems of high complexity, low efficiency, and high cost in programming different chips on a circuit board have existed for a long time in the prior art, and therefore it is necessary to propose a technical means for improvement to solve such problems.

### SUMMARY OF THE INVENTION

In view of the prior art, at present there are problems of high complexity, low efficiency, and high cost in programming different chips on circuit board, the present invention discloses a system and a method for programming chips on circuit board through boundary scan technology.

The system for programming chips on circuit board through boundary scan technology disclosed in the present invention includes: a target circuit board, a read and write device, and a client. The target circuit board further includes a plurality of chips and a Joint Test Action Group (JTAG) interface, The read and write device further includes a first connection module, a verification module, a second connection module, a test module, a third connection module, and a programming module. The client further includes a read module and a transmission module.

The JTAG interface and each chip are connected in series according to boundary scan technology to form a boundary scan chain.

An electrical connection is formed between the read and write device and the JTAG interface through an external connection. The first connection module of the read and write device is used for receiving verification information. The verification module of the read and write device is used for verifying the verification information. The second connection module of the read and write device receives a test signal when the verification information passes the verification. The test module of the read and write device is used for performing a complete test on the boundary scan chain according to the test signal through the JTAG interface by using the boundary scan technology. The third connection module of the read and write device receives programming data when the test module completes the test on the boundary scan chain. The programming module of the read and write device is used for selecting a corresponding chip according to the programming data, and pushes the programming data to the selected chip through the JTAG interface by using the boundary scan technology to perform programming.

The read module of the client is used for reading the programming data. The transmission module of the client is used for establishing a connection to the read and write device, and providing the verification information, the test signal, and the programming data to the read and write device.

The method for programming chips on circuit board through boundary scan technology disclosed in the present invention includes the following steps:

First, provide a target circuit board having a plurality of chips and a JTAG interface, in which the JTAG interface and each chip are connected in series according to a boundary scan technology to form a boundary scan chain. Next, form an electrical connection between a read and write device and the JTAG interface through an external connection. Next, a client establishes a connection to the read and write device and provides verification information to the read and write device. Next, the read and write device verifies the verification information. Next, when the verification information passes the verification by the read and write device, the client provides a test signal to the read and write device. Next, the read and write device performs a complete test on the boundary scan chain according to the test signal through the JTAG interface by using the boundary scan technology. Next, when the read and write device completes the test on the boundary scan chain, the client reads programming data and provides the programming data to the read and write device. Finally, the read and write device selects a corresponding chip according to the programming data, and pushes the programming data to the selected chip through the JTAG interface by using the boundary scan technology to perform programming.

The system and method disclosed in the present invention are discussed above, and the difference from the prior art lies in that, in the present invention, each chip and a JTAG interface on a target circuit board are connected in series according to a boundary scan technology to form a boundary scan chain, a read and write device selects a corresponding chip according to programming data, and pushes the programming data to the selected chip through the JTAG interface by using the boundary scan technology to perform programming.

Through the technical means above, the present invention is capable of achieving the technical effects of simplifying the programming of different chips on circuit board and enhancing the efficiency of programming chips.

### BRIEF DESCRIPTION OF THE DRAWINGS

The invention will become more fully understood from the detailed description given herein below illustration only, and thus is not limitative of the present invention, and wherein:

FIG. 1 is a block diagram of a system for programming chips on circuit board through boundary scan technology according to the present invention.

FIG. 2 is a schematic view of a boundary scan chain for programming chips on circuit board through boundary scan technology according to the present invention.

FIG. 3 is a flow chart of a method for programming chips on circuit board through boundary scan technology according to the present invention.

### DETAILED DESCRIPTION OF THE INVENTION

The implementation manners of the present invention are illustrated in detail below with reference to the accompanying drawings and the embodiments, thereby providing thorough understanding of the implementation processes on how the present invention adopts the technical means to solve the technical problems and achieve the technical effects and enabling the implementation there accordingly.

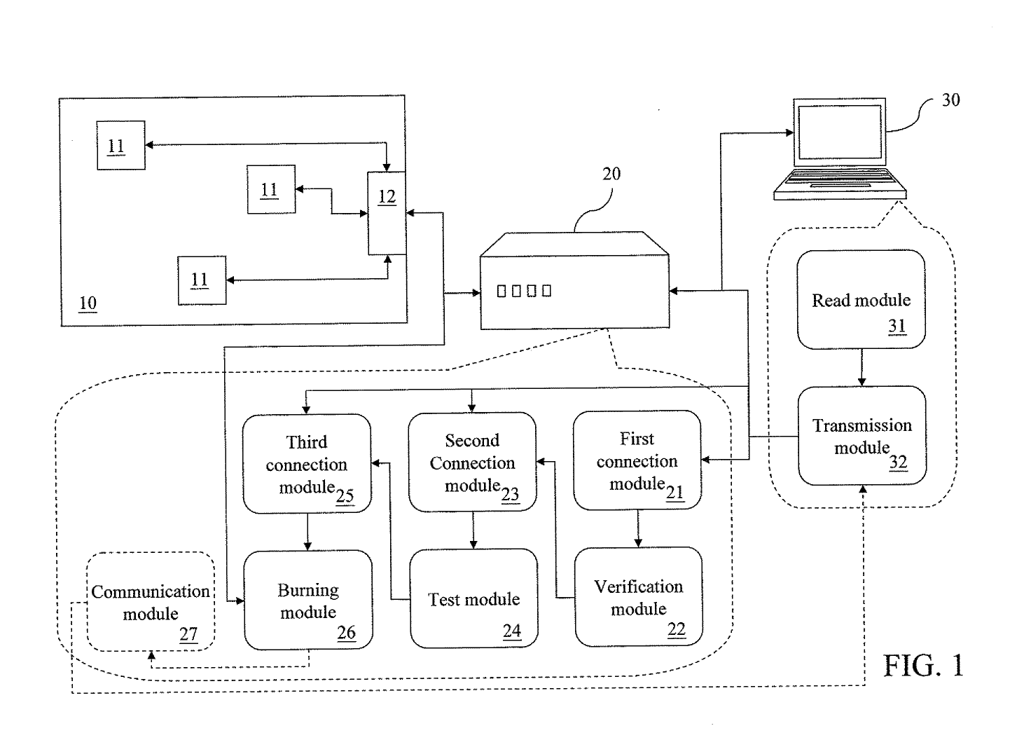

A system for programming chips on circuit board through boundary scan technology and disclosed in the present invention is illustrated below first. Please refer to FIG. 1. FIG. 1 is a block diagram of a system for programming chips on circuit board through boundary scan technology according to the present invention.

The system for programming chips on circuit board through boundary scan technology disclosed in the present invention includes: a target circuit board 10, a read and write device 20, and a client 30. The target circuit board 10 further includes a plurality of chips 11 and a JTAG interface 12. The read and write device 20 further includes a first connection module 21, a verification module 22, a second connection module 23, a test module 24, a third connection module 25, and a programming module 26. The client 30 further includes a read module 31 and a transmission module 32.

The plurality of chips 11 included in the target circuit board 10 is required to support the JTAG 1149.1 standard, and currently for example, Intel 80386™ and Intel 80486 processors and above, Motorola 68040 microprocessor, Xilinx XC3000 series field-programmable gate arrays (FPGAs) and above, Texas Instruction C40 series digital signal processor (DSP) chips, and DEC Alpha 21164 series reduced instruction set computing (RISC) chips, and the like are capable of supporting the JTAG 1149.1 standard. Also, the chip 11 may be an EEPROM chip, a non-volatile random access memory chip, or a flash memory chip, which are only examples for illustration, and the application scope of the present invention is not limited thereto.

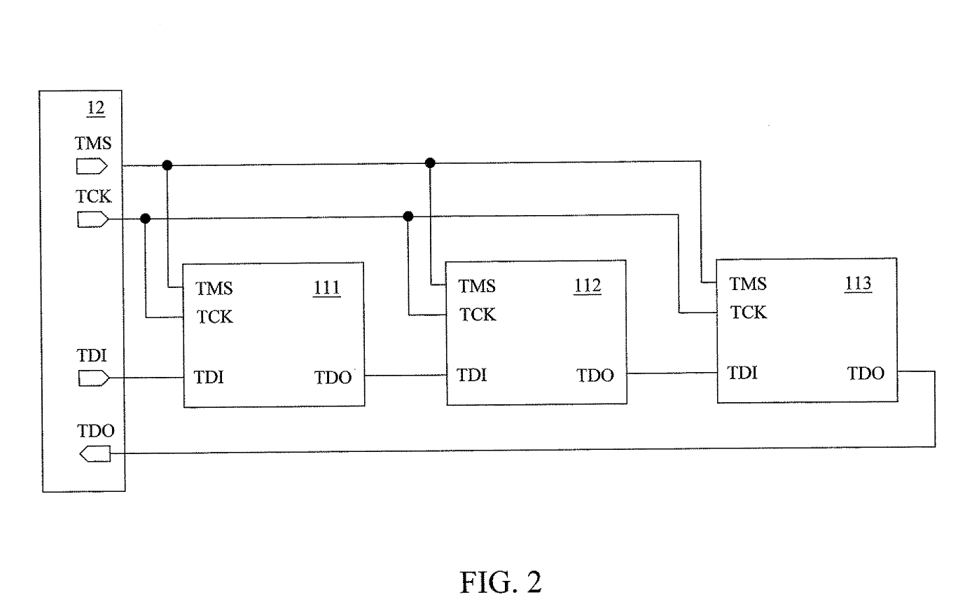

Next, please refer to FIG. 2. FIG. 2 is a schematic view of a boundary scan chain for programming chips on circuit board through boundary scan technology according to the present invention.

In FIG. 2, the first chip 111, the second chip 112, and the third chip 113 are used for illustration for a boundary scan chain formed by a JTAG interface and chips connected in series, which is only an example for illustration, and the application scope of the present invention is not limited thereto.

First, the first chip 111, the second chip 112, and the third chip 113 all include a test data input (TDI) pin, a test data output (TDO) pin, a test clock (TCK) pin, and a test mode select input (TMS) pin.

The TCK pins of the first chip 111, the second chip 112, and the third chip 113 are electrically connected to the TCK pin of the JTAG interface 12, and the TMS pins of the first chip 111, the second chip 112, and the third chip 113 are electrically connected to the TMS pin of the JTAG interface 12.

The TDI pin of the JTAG interface 12 is electrically connected to the TDI pin of the first chip 111, the TDO pin of the first chip 111 is electrically connected to the TDI pin of the second chip 112, the TDO pin of the second chip 112 is electrically connected to the TDI pin of the third chip 113, and the TDO pin of the third chip 113 is electrically connected to the TDO pin of the JTAG interface 12.

Through the electrical connections above, the first chip 111, the second chip 112, the third chip 113, and the JTAG interface 12 are connected in series to form a boundary scan chain, that is, the JTAG interface 12 and each chip (the first chip 111, the second chip 112, and the third chip 113) are connected in series according to a boundary scan technology to form a boundary scan chain.

It should be noted that the communication protocol of the JTAG interface 12 is required to be serial transmission as other serial device interfaces, for example, a serial peripheral interface (SPI) bus, which are only examples for illustration, and the application scope of the present invention is not limited thereto.

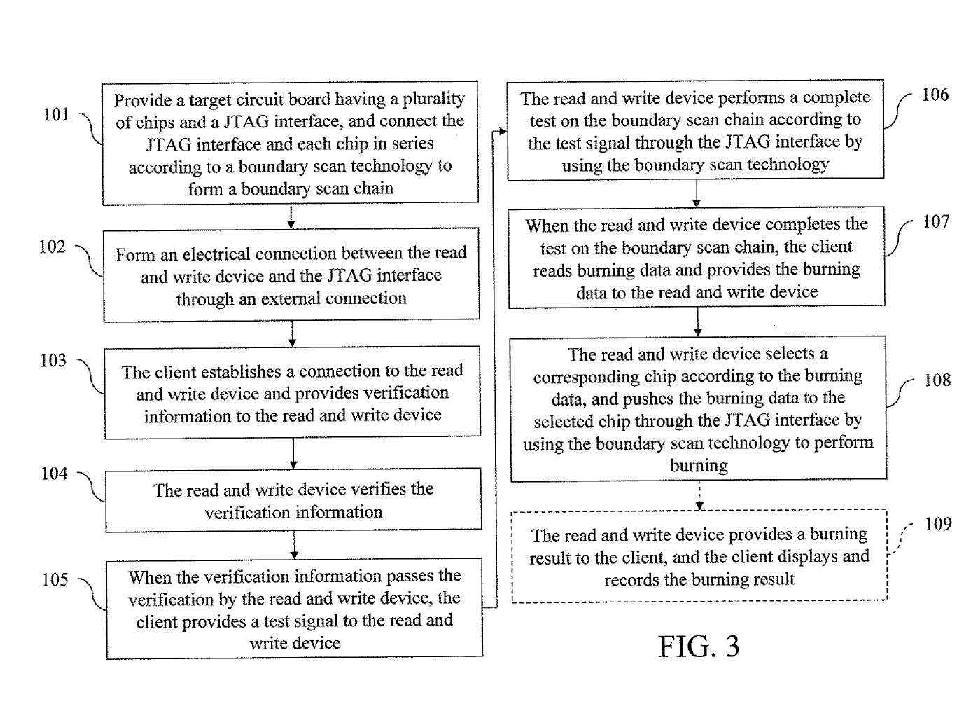

Next, please refer to FIG. 1 and FIG. 3 at the same time. FIG. 3 is a flow chart of a method for programming chips on circuit board through boundary scan technology according to the present invention.

When a user needs to program chips 11 in a target circuit board 10, connect a JTAG interface 12 and each chip 11 in series according to a boundary scan technology to form a boundary scan chain (Step 101). First, the target circuit board 10 is required to be at a fully disconnected state. Next, form an electrical connection between the read and write device 20 and the JTAG interface 12 through an external connection (Step 102).

The transmission module 32 of the client 30 is then capable of establishing a connection to the read and write device 20 through a wired transmission manner or a wireless transmission manner (Step 103). The client 30 may be a notebook computer, a tablet computer, a handheld device (for example, a smart phone, a personal digital assistant (PDA), and the like). Also, the transmission module 32 of the client 30 establishes a connection to the read and write device 20 in a wired transmission manner or a wireless transmission manner, for example, in the manner of a wired network or a transmission cable, and the like. The transmission module 32 of the client 30 establishes a connection to the read and write device 20 in a wireless transmission manner, for example, in the manner of Near Field Communication (NFC), Bluetooth (Bluetooth) or WIFI, and the like, which are only examples for illustration, and the application scope of the present invention is not limited thereto.

After the transmission module 32 of the client 30 establishes a connection to the read and write device 20, the first connection module 21 of the read and write device 20 may acquire verification information from the transmission module 32 of the client 30 (Step 103), and also the verification module 22 of the read and write device 20 may verify the verification information (Step 104). Please refer to prior art for the process that the verification module 22 of the read and write device 20 verifies the verification information, which is no longer described here in the present invention, and the existing verification mechanism may be properly applied in the present invention.

When the verification information of the client 30 passes the verification by the verification module 22 of the read and write device 20, it is determined that the client 30 is a legal client, and the client 30 is able to program the chip 11 in the target circuit board 10 through the read and write device 20. Otherwise, when the verification information of the client 30 fails to pass the verification by the verification module 22 of the read and write device 20, it is determined that the client 30 is an illegal client, and the client 30 is unable to program the chip 11 in the target circuit board 10 through the read and write device 20.

When the verification information of the client 30 passes the verification by the verification module 22 of the read and write device 20, the second connection module 23 of the read and write device 20 acquires a test signal from the transmission module 32 of the client 30 (Step 105). After the second connection module 23 of the read and write device 20 receives the test signal, the test module 24 of the read and write device 20 performs a complete test on the boundary scan chain according to the test signal through the JTAG interface 12 by using the boundary scan technology (Step 106), so as to guarantee that the boundary scan chain is capable of provide normal push of data.

When the test module 24 of the read and write device 20 completes the test on the boundary scan chain, the read module 31 of the client 30 reads programming data, and the transmission module 32 of the client 30 provides the programming data read by the read module 31 of the client 30 to the read and write device 20, and the third connection module 25 of the read and write device 20 is then able to receive the programming data provided by the transmission module 32 of the client 30 (Step 107).

After the third connection module 25 of the read and write device 20 receives the programming data provided by the transmission module 32 of the client 30, the programming module 26 of the read and write device 20 then selects a corresponding chip, and pushes the programming data to the selected chip 11 through the JTAG interface 12 by using the boundary scan technology, so as to find the timing and protocol required for the programming chip 11 through analogy to program the selected chip 11 (Step 108), and at this time, the read and write device 20 provides the selected chip 11 with power supply during programming.

When the programming module 26 of the read and write device 20 completes the programming of the selected chip 11, a communication module 27 further included in the read and write device 20 provides a programming result to the transmission module 32 of the client 30, and after acquiring the programming result provided by the communication module 27 of the read and write device 20, the transmission module 32 of the client 30 is able to display and record the programming result (Step 109), thereby determining the programming result of the selected chip.

Next, after the chip 11 of the target circuit board 10 finishes the programming, the client 30 and the read and write device 20 are disconnected, and the electrical connection relationship between the read and write device 20 and the JTAG interface 12 is removed, so as to complete the programming of the chip on the target circuit board 10.

In conclusion, it can be seen that the difference between the present invention and the prior art lies in that in the present invention, each chip and a JTAG interface on a target circuit board are connected in series according to a boundary scan technology to form a boundary scan chain, a read and write device selects a corresponding chip according to programming data, and pushes the programming data to the selected chip through the JTAG interface by using the boundary scan technology to perform programming.

Such a technical means is capable of solving the problems of high complexity, low efficiency, and high cost in programming different chips on circuit board at present in the prior art, thereby achieving the technical effects of simplifying the programming of different chips on circuit board and enhancing the efficiency of programming chips.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A system for programming chips on circuit board through boundary scan technology, comprising:
a target circuit board, the target circuit board further comprising:
a plurality of chips; and
a Joint Test Action Group (JTAG) interface, the JTAG interface and each chip being connected in series according to a boundary scan technology to form a boundary scan chain;
a read and write device, the read and write device being electrically connected to the JTAG interface through an external connection, and the read and write device further comprising:
a first connection module, used for receiving verification information;
a verification module, used for verifying the verification information;
a second connection module, used for, when the verification information passes the verification, receiving a test signal;
a test module, used for performing a complete test on the boundary scan chain according to the test signal through the JTAG interface by using the boundary scan technology;
a third connection module, used for, when the test module completes the test on the boundary scan chain, receiving programming data; and
a programming module, used for selecting a corresponding chip according to the programming data, and pushing the programming data to the selected chip through the JTAG interface by using the boundary scan technology to perform programming; and
a client, the client further comprising:
a read module, used for reading the programming data; and
a transmission module, used for establishing a connection to the read and write device, and providing the verification information, the test signal, and the programming data to the read and write device.

2. The system for programming chips on circuit board through boundary scan technology according to claim 1, wherein the transmission module establishes a connection to the read and write device in a wired transmission manner or a wireless transmission manner, and the wireless transmission manner comprises Near Field Communication (NFC), Bluetooth and WIFI.

3. The system for programming chips on circuit board through boundary scan technology according to claim 1, wherein the read and write device further provides each chip with power supply during chip programming.

4. The system for programming chips on circuit board through boundary scan technology according to claim 1, wherein the read and write device further comprises a communication module, used for transmitting a programming result to the transmission module, and the client displays and records the programming result.

5. A method for programming chips on circuit board through boundary scan technology, comprising:
providing a target circuit board having a plurality of chips and a Joint Test Action Group (JTAG) interface, the JTAG interface and each chip being connected in series according to a boundary scan technology to form a boundary scan chain;
forming an electrical connection between a read and write device and the JTAG interface through an external connection;
establishing, by a client, a connection to the read and write device, and providing verification information to the read and write device;
verifying, by the read and write device, the verification information;
when the verification information passes the verification by the read and write device, providing, by the client, a test signal to the read and write device;
performing, by the read and write device, a complete test on the boundary scan chain according to the test signal through the JTAG interface by using the boundary scan technology;
when the read and write device completes the test on the boundary scan chain, reading, by the client, programming data and providing the programming data to the read and write device; and
selecting, by the read and write device, a corresponding chip according to the programming data, and pushing the programming data to the selected chip through the JTAG interface by using the boundary scan technology to perform programming.

6. The method for programming chips on circuit board through boundary scan technology according to claim 5, wherein the step of establishing, by the client, a connection to the read and write device is establishing a connection to the read and write device in a wired transmission manner or a wireless transmission manner, the wireless transmission manner comprises Near Field Communication (NFC), Bluetooth (Bluetooth), and WIFI.

7. The method for programming chips on circuit board through boundary scan technology according to claim 5, wherein in the step of forming an electrical connection between the read and write device and the JTAG interface, and the read and write device further provides each chip with power supply during chip programming.

8. The method for programming chips on circuit board through boundary scan technology according to claim 5, further comprising the steps of providing, by the read and write device, a programming result to the client, and displaying and recording, by the client, the programming result.
